(19) United States
(12) Patent Application Publication
(10) Pub. No.: US 2005/0083655 A1
(43) Pub. Date: Apr. 21, 2005

(54) Dielectric thermal stack for the cooling of high power electronics

(75) Inventors: Vivek Jairazbhoy, Farmington Hills, MI (US); Prathap A. Reddy, Farmington Hills, MI (US); Mohan Paruchuri, Canton, MI (US); Jay D. Baker, W. Bloomfield, MI (US)

Correspondence Address: Robert K. Fergan, Esq.;BRINKS HOFER GILSON & LIONE, P.O. Box 10395, Chicago, IL, 60610, US

(73) Assignee: Visteon Global Technologies, Inc.

(21) Appl. No.: 10/685,931

(22) Filed: Oct. 15, 2003

(51) Int. Cl. H05K 7/20

(52) U.S. Cl. 361/699

(57) ABSTRACT

A system for dissipating heat in an electronic power module is provided. The system includes a semiconductor die, a substrate, and a heat sink in which is contained a first fluid, and a conduit through which a second fluid is permitted to flow. The substrate is attached on one surface to the die and configured to conduct heat from the die. The heat sink is attached to another surface of the substrate and transfers heat from the die to the first fluid contained therein, which evaporates due to the heat provided by the substrate. The fluid is condensed on a condensing wall cooled by the second fluid, which flows across the outer surface of the condensing wall, to transport heat away from the heat sink.

### BACKGROUND

1. Field of the Invention

The present invention generally relates to the dissipation of heat from a power module. More specifically, the invention relates to the dissipation of heat from a power module utilizing a vapor fluid heat sink.

2. Description of Related Art

In high power electronic applications, such as those used in electrical vehicle designs, a significant amount of heat is generated in semiconductor devices that control the switching of power. These thermal losses can adversely affect the performance and reliability of the device by causing the device to overheat. When the device overheats, the junction temperature rises to a level where the device fails to function. In addition, the devices and interconnects may also fail due to thermal expansion effects, as a mismatch in thermal expansion characteristics can cause solder joint cracking. Therefore, it is advantageous to maximize the capability of heat dissipation and to minimize the effects of thermal expansion.

### SUMMARY

In satisfying the above need, as well as overcoming the enumerated drawbacks and other limitations of the related art, the present invention provides a system for dissipating heat in semiconductor devices, and particularly in an electronic power module. The system includes a semiconductor die, a substrate, a heat sink containing a first fluid, and a base containing a second fluid for cooling the heat sink. The substrate is attached to both the die and the heat sink and is configured to conduct heat from the die to the heat sink. Within the heat sink, the first fluid is evaporated due to the heat provided by the substrate and is condensed, on a condensing wall of the chamber due to cooling provided by the second fluid. The outer surface of the condensing wall is located such that the second fluid flow across it to transport heat away from the heat sink.

In another aspect of the invention, the substrate is made of metal and more specifically may be made of copper, porous graphite, a graphite foam, or a metal foam.

In a further aspect of the invention, the first fluid is a dielectric fluid providing electrical isolation. In addition, the substrate can be made of a porous material configured to draw the first fluid towards the die.

In yet another aspect of the invention, the outer wall of the chamber includes fins that increase the surface area thereby improving the heat transfer between the outer wall and the second fluid. Further, the fins may include a porous material, such as graphite or metal foam, to further increase the surface area and improve heat transfer between the chamber and second fluid.

In yet another aspect of the invention, the die is attached to the substrate using a phase changing solder. Further, a sealant is attached between the die and the substrate to encapsulate and contain the phase changing solder. Because of its phase changing capability at the requisite temperature range, the solder accommodates differences in thermal expansion between the die and substrate.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a top plan view of a power module configured for dissipating heat in accordance with the present invention;

FIG. 2 is a cross-sectional view of the power module shown in FIG. 1 generally taken along section line Z-Z;

FIG. 3 is a cross-sectional view of a power module similar to that of FIG. 2, illustrating a second embodiment, a system for dissipating heat in accordance with the present invention;

FIG. 4 is a cross-sectional view of a power module including a system for dissipating heat, the system having a metal foam substrate in accordance with the present invention;

FIG. 5 is a cross-sectional view of a power module including a system to dissipate heat, the system including bellows in accordance with the present invention; and

FIG. 6 is a cross-sectional view of a power module including a system for dissipating heat, the system including metal foam attached to the chamber and configured to dissipate heat into the second fluid.

### DETAILED DESCRIPTION

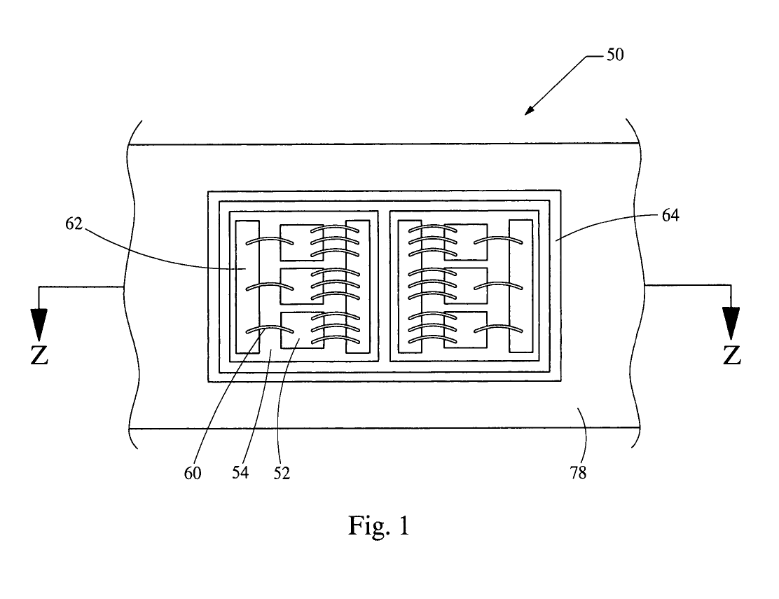

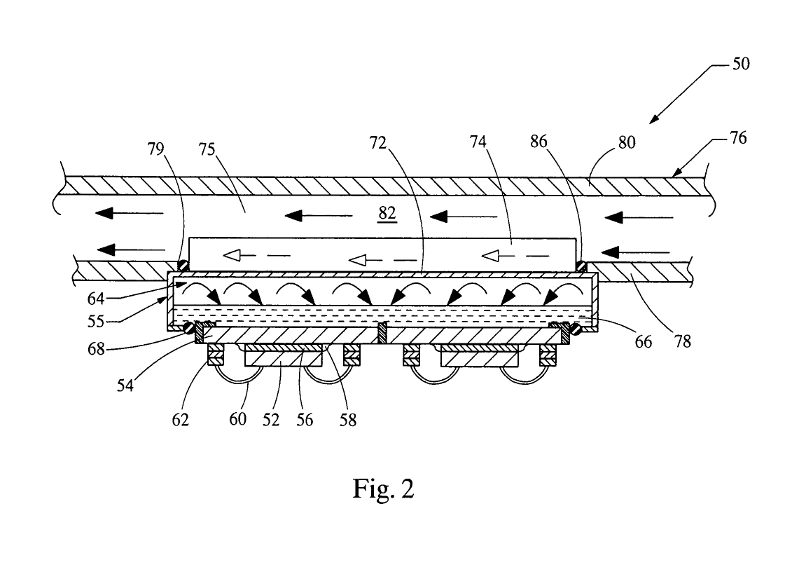

Referring now to FIGS. 1 and 2, a system embodying the principles of the present invention is illustrated therein and generally designated at 50. The system 50 includes a die 52, a substrate 54, heat sink 55 containing a first fluid and a base 76 containing a second fluid 82.

The die 52 is electrically connected to bond pads 62 formed on the substrate 54 through the wire bonds 60. The die 52 is thermally connected to the substrate 54 using a phase changing or liquefiable solder 56. Alternatively, this thermal connection may be made through more common solder or thermally conductive adhesive. When phase changing solder 56 is used, a sealant 58 is attached between the die 52 and the substrate 54 and configured to encapsulate the liquefiable solder 56. However, other more common attachment techniques may be used. The substrate 54 is made of a material with good thermal conductivity. Metal, specifically copper, is an example of an appropriate material for the substrate 54.

As is well known, the die 52 will generate heat during its normal operation that needs to be dissipated to ensure proper functioning of the die 52. To dissipate the heat, the substrate 54 is attached to the heat sink 55. The heat sink 55 includes a chamber 64 and a fluid 66. The chamber 64 contains fluid 66 which may be a dielectric fluid to prevent electrical shorts. Heat conducted through the substrate 54 causes the fluid 66 to evaporate. The fluid vapor rises to the top wall 72 of the chamber 64 and the vapor condenses on an inner surface of the wall 72. Upon condensing, the fluid 66 returns to the bottom of the chamber 64, defined by the substrate 54, due to gravity and is available for revaporization to again transport heat away from the substrate 54. To ensure a fluid tight seal between the substrate 54 and the heat sink 55, a seal member 68 is located between the heat sink 55 and the substrate 54.

The heat sink 55 is further attached to a base 76 having a first wall 78 and a second wall 80 defining a channel 75 in which is contained a second fluid 82 that flows therethrough.

Defined in the first wall 78 is an aperture 79, about which is mounted the heat sink 55. The outer surface of the wall 72 of the heat sink 55 is located in the aperture 79 such that the fluid 82 flows across the outer surface of the wall 72 to dissipate the heat away from the power module 50. To increase surface area and aid in dissipating the heat, the outer surface of the wall 72 may include fins 74. Further, a seal 86 is located between the first wall 72 of the base 76 and the heat sink 55 to provide a fluid tight seal therebetween.

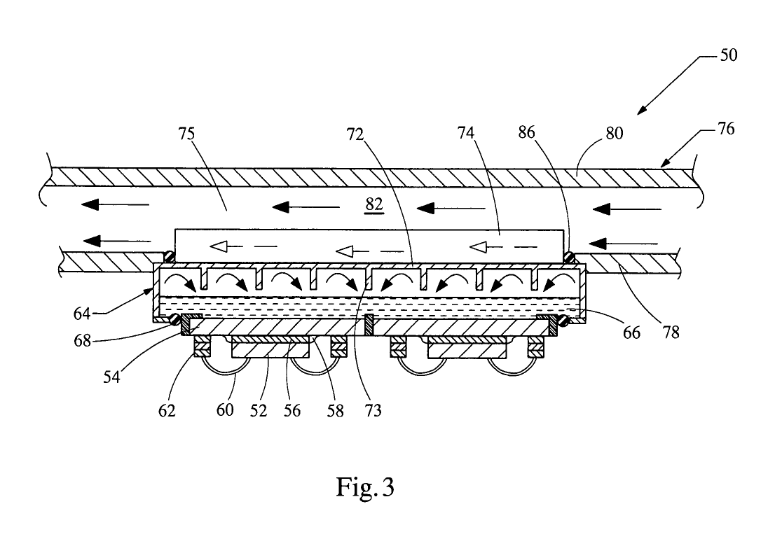

Now referring to FIG. 3, the system may also include fins 73 integrated into the inner surface of the wall 72 of the chamber 64. The fins 73 increase the surface area available for condensing the fluid 66 to improve the transfer of heat away from the substrate 54.

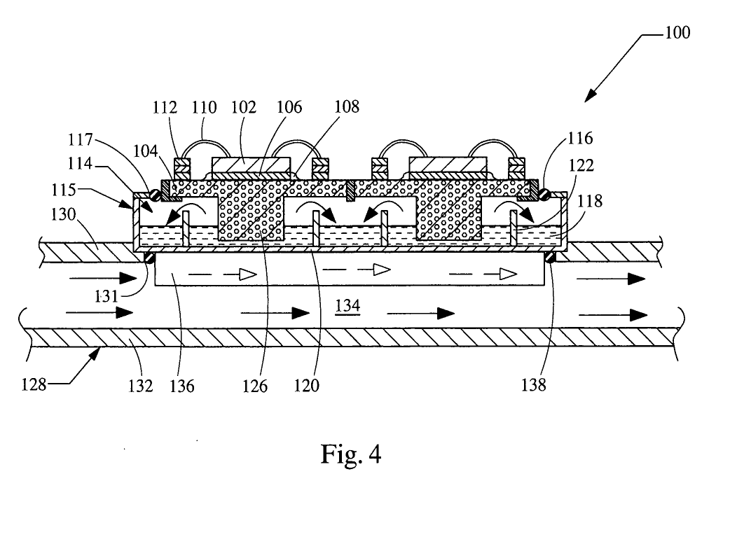

Now referring to FIG. 4, the die 102 is attached to the bond pads 112 of the module 100 through the wire bond 110. Further, the die 102 is attached to the substrate 104 providing a sink to transport heat away from the die 102. The die 102 may be thermally connected to the substrate using a liquefiable solder 106. A sealant 108 is attached between the die 102 and the substrate 104 and configured to contain liquefiable solder 106. However, other more common attachment methods may be used. The substrate 104 is made of a material with good thermal conductivity. Metal, specifically copper, is an example of an appropriate material for the substrate 104. In addition, the substrate 104 may include a porous material. The porous material may be made of a thermally conductive graphite foam, or metal foam.

The substrate 104 is attached over an aperture 117 in the heat sink 115. The heat sink 115 forms a chamber 114 that contains a fluid 118. The fluid 118 may be a dielectric fluid to prevent electrical shorts. The chamber 114 can be refilled with fluid in a service operation through a service aperture in the walls of the chambers (not shown). The service aperture is plugged and sealed after the filling operation. A portion of the porous material extends from the substrate 104 and is partially immersed in the dielectric fluid 118. The fluid 118, in direct contact with the porous material of the substrate 104, is drawn continuously by capillary action into the pores and towards the heat source. Thus, the fluid is continuously heated during operation by the substrate 104. When the temperature exceeds the boiling point, the fluid is evaporated. Migration of vapor within the chamber promotes lateral heat spreading. The vapor condenses on the surface of cold plates 122. The condensation on the cold plates 122 transfers latent heat from the vapor to the cold plates 122.

Upon condensing, the fluid 118 falls to the bottom of the chamber 104 due to gravity and is available for revaporization to transport heat away from the substrate 104. The chamber 114 may have a seal 116 attached between the chamber 114 and the substrate 104 to contain the fluid 118 in the chamber 114.

The chamber 114 is attached to a channel 128 containing a second fluid 134. The channel 128 has a first wall 130 and a second wall 132. The first wall 130 has an aperture 131 and the outer surface of the wall 120 of the chamber 114 is located in the aperture 131 such that fluid 134 flows across the outer surface of the wall 120 to dissipate the heat from the cold plates 122 and away from the power module 100. The outer surface of the wall 120 may include fins 136 which increase the surface area and aid in dissipating the heat into the fluid 134. Further, a seal 138 is attached between the first wall 130 of the channel 128 and the chamber 114 to contain the fluid 134 in the channel 128.

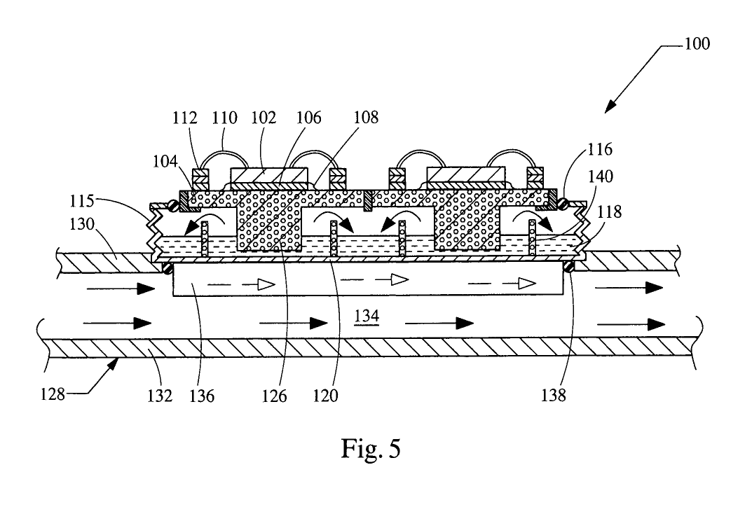

Now referring to FIG. 5, in another aspect of the invention, the cold plates 140 may also be made of a porous material. The porous material increases the surface area of the plates 140 and aids in the transfer of heat from the fluid 118 to the cold plates 140. Further, bellows 115 may be provided on one or both sides of the chamber 114. The bellows 115 permit expansion of the chamber 114 to fine tune the internal operating pressure.

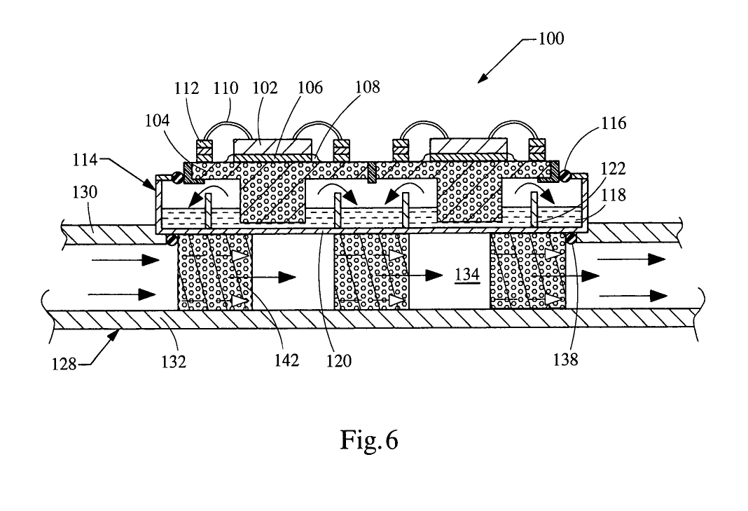

Now referring to FIG. 6, the outer surface of the wall 120 may include fins 142 made of a porous material. The porous material may include a graphite or metal foam and is used as a heat sink for the wall 120. The ultra high surface area of the porous material enhances the rate of heat transfer to the coolant stream of the second fluid 134. The fluid 134 can be forced through the pores of the metal foam to further promote heat transfer.

As a person skilled in the art will readily appreciate, the above description is meant as an illustration of implementation of the principles this invention. This description is not intended to limit the scope or application of this invention in that the invention is susceptible to modification, variation and change, without departing from spirit of this invention, as defined in the following claims.

1. A heat dissipating system for an electronic power module, the system comprising:
a semiconductor die;
a substrate attached to the die so as to conduct heat from the die;
a heat sink attached to the substrate, wherein portions of the heat sink define a chamber, the chamber including a wall further defining a condensing surface;
a first fluid contained in the chamber; and
a base having portions defining a fluid passageway therein, and a second fluid within the passageway flows across an outer surface of the wall of the heat sink to transport the heat away from the heat sink.

2. The system according to claim 1, wherein the substrate is formed of metal.

3. The system according to claim 2, wherein the substrate is substantially copper.

4. The system according to claim 1, wherein the heat sink includes portions defining an aperture, and the substrate being mounted over the aperture.

5. The system according to claim 1, wherein the first fluid is a dielectric fluid.

6. The system according to claim 5, wherein a seal is located between the substrate and the chamber.

7. The system according to claim 1, wherein the outside surface of the wall of the heat sink includes at least one fin extending therefrom and providing additional surface area for dissipating heat.

8. The system according to claim 1, wherein portions of the base define an aperture, and the heat sink being mounted over the aperture.

9. The system according to claim 1, further comprising a seal located between the wall of the conduit and the wall of the heat sink.

10. The system according to claim 1, wherein the second fluid is substantially water.

11. The system according to claim 1, wherein the die is attached to the substrate by a phase changing solder material.

12. The system according to claim 11, further comprising a sealant attached between the die and the substrate to contain the phase changing solder material.

13. The system according to claim 1, wherein the heat sink includes fins on the condensing surface to provide additional surface area for improved condensation.

14. The system according to claim 1, the heat sink has a predefined orientation wherein the orientation is such that gravity causes the first fluid to return to the substrate after it has condensed on the condensing surface.

15. The system according to claim 1, wherein the substrate includes metal foam.

16. The system according to claim 1, wherein the substrate includes a metal foam member extending from the substrate, the metal foam configured to draw the first fluid towards the die.

17. The system according to claim 16, wherein the condensing surface includes plates extending therefrom into the first fluid.

18. The system according to claim 1, wherein the heat sink includes bellows configured to accommodate thermal expansion of the first fluid therein.

19. The system according to claim 1, further comprising metal foam attached to the outer surface of the chamber, the metal foam having passageways defined therethrough to allow the second fluid to flow through the metal foam.

20. A heat dissipating system for an electronic power module, the system comprising:
a semiconductor die;
a substrate attached to the die so as to conduct heat from the die;
a heat sink attached to the substrate, the heat sink including portions defining an aperture and the substrate being mounted to the heat sink over the aperture such that the heat sink and substrate cooperatively define a chamber, the chamber including a wall further defining a condensing surface;
a first fluid contained in the chamber; and
a base having portions defining a fluid passageway therein, and a second fluid within the passageway flows across an outer surface of the wall of the heat sink to transport the heat away from the heat sink.

21. The system according to claim 1, wherein the substrate includes metal foam.

22. The system according to claim 21, wherein the substrate includes substantially copper.

23. The system according to claim 20, wherein the first fluid is a dielectric fluid.

24. The system according to claim 20, wherein the substrate forms a wall of the chamber.

25. The system according to claim 24, wherein a seal is located between the substrate and the chamber.

26. The system according to claim 25, wherein the outside surface of the wall of the chamber includes at least one fin to provide additional surface area for dissipating heat.

27. The system according to claim 20, wherein a wall of the base has an aperture and the outside surface of the wall of the chamber is located in the aperture to allow the second fluid to flow across the outer surface of the wall of the chamber.

28. The system according to claim 27, further comprising a seal located between the wall of the channel and the outside surface of the wall of the chamber.

29. The system according to claim 20, wherein the second fluid includes substantially water.

30. The system according to claim 20, wherein the die is attached to the substrate using a phase changing solder material.

31. The system according to claim 30, further comprising a sealant attached between the die and the substrate to contain the phase changing solder material.

32. The system according to claim 20, wherein the heat sink includes fins on the condensing surface to provide additional surface area for improved condensation.

33. The system according to claim 20, wherein the orientation of the chamber is such that gravity causes the first fluid to return to the substrate after it has condensed on the condensing surface.

34. The system according to claim 20, wherein the porous material of the substrate is configured to draw the first fluid towards the die.

35. The system according to claim 20, wherein the condensing surface includes plates extending through the first fluid.

36. The system according to claim 20, wherein the heat sink includes bellows configured to accommodate thermal expansion of the dielectric fluid.

37. The system according to claim 20, further comprising metal foam attached to the outer surface of the chamber and configured to allow the second fluid to flow through the metal foam.
